(19) United States
(12) Patent Application Publication
(10) Pub. No.: US 2012/0104523 A1
(43) Pub. Date: May 3, 2012

(54) Solid-state imaging device manufacturing method of solid-state imaging device, and electronic apparatus

(75) Inventor: Harumi Ikeda, Kanagawa (JP)

(73) Assignee: Sony Corporation, Tokyo (JP)

(21) Appl. No.: 13/200,934

(22) Filed: Oct. 5, 2011

(30) Foreign Application Priority Data
Oct. 27, 2010 (JP) 2010-241490

(51) Int. Cl. H01L 31/0232

(52) U.S. Cl. 257/432; 257/435; 438/73; 257/443; 257/E31.127

(57) ABSTRACT

A solid-state imaging device includes a substrate, a photodiode region which is formed in the substrate and generates a signal charge using photoelectric conversion of light which is incident from a back surface side of the substrate, a wiring layer which is formed on a front surface side of the substrate which is a side opposite to a light incidence surface, a light-blocking wiring which is formed in the wiring layer and is formed in a region which covers at least a portion of the photodiode region, and a connection portion which supplies a predetermined voltage from the light-blocking wiring to the photodiode region.

### BACKGROUND

The present disclosure relates to a back side illumination type of solid-state imaging device, and in addition, to a manufacturing method of the solid-state imaging device and an electronic apparatus which uses the solid-state imaging device.

In the past, as a solid-state imaging device which is used in a digital camera or a video camera, a CCD type of solid-state imaging device and a CMOS type of solid-state imaging device are known. In these solid-state imaging devices, a reception section is formed for each pixel of which a plurality is formed in a two-dimensional matrix format, and in the reception section, a signal charge is generated according to the amount of light received. Then, an image signal is obtained by transferring and amplifying the signal charge which is generated in the reception section.

In addition, in recent years, a back side illumination type of solid-state imaging device is proposed where light is irradiated from a side opposite to a side where a wiring layer is formed on a substrate (refer to Japanese Unexamined Patent Application Publication No. 2005-268476 described below). In the back side illumination type of solid-state imaging device, since the wiring layer, circuit elements, and the like are configured on a light irradiation side, it is possible to increase the aperture ratio of the reception section which is formed on the substrate, and since irradiation light is irradiated onto the reception section without being reflected by the wiring layer or the like, improvement in sensitivity is able to be achieved.

However, in the back side illumination type of solid-state imaging device, light which is incident from a back surface side of the substrate is transmitted through the substrate and reaches the wiring layer on the front surface side of the substrate, and the transmitted light is diffusely reflected by the wiring layer and irradiated on adjacent pixels, and thus there is a problem that color mixing occurs. Accordingly, in the back side illumination type of solid-state imaging device, it is necessary to prevent color mixing due to transmitted light which is transmitted through the substrate.

In addition, in the solid-state imaging device, in order to suppress dark current which is generated at a boundary of the semiconductor substrate and an insulating film, there is a typical method where a high-concentration p-type semiconductor region is formed using ion implantation on the front surface of an n-type semiconductor substrate, that is, the boundary of the semiconductor substrate and the insulating film. However, there is a limit to forming the p-type semiconductor region to be shallow and concentrated using ion implementation. As a result, when the concentration of impurities in the p-type semiconductor region is further increased in order to suppress dark current, this time, the p-type semiconductor region is thickly formed and the n-type semiconductor region which configures a photodiode is reduced and thus there is a problem that the saturation charge amount Qs is reduced.

In the back side illumination type of solid-state imaging device, in order to form the p-type semiconductor region which suppresses dark current to be shallower, a configuration is proposed in Japanese Unexamined Patent Application Publication No. 2005-268476 where the potential of the boundary on the side opposite to the light incidence surface of the substrate is controlled using a control gate.

However, in the configuration in Japanese Unexamined Patent Application Publication No. 2005-268476, since the control gate is formed of polysilicon and transmits light, the blocking of the transmitted light as described above is not possible and it is not possible to solve the problem of color mixing.

### SUMMARY

It is desirable that a back side illumination type of solid-state imaging device, which suppresses dark current which is generated at a boundary on a side opposite to a light incidence surface of a substrate and which is able to suppress color mixing due to light which is transmitted through the substrate, and a manufacturing method of the solid-state imaging device are proposed. Furthermore, it is desirable that an electronic apparatus which uses the solid-state imaging device is proposed.

A solid-state imaging device according to an embodiment of the disclosure is provided with a substrate, a photodiode region which is formed on the substrate, a wiring layer, a light-blocking wiring, and a connection portion.

The photodiode region is formed in the substrate and generates a signal charge using photoelectric conversion of light which is incident from a back surface side of the substrate. The wiring layer is formed on a front surface side of the substrate which is a side opposite to a light incidence surface. The light-blocking wiring is formed in the wiring layer and is formed in a region which covers at least a portion of the photodiode region. The connection portion supplies a predetermined voltage from the light-blocking wiring to the photodiode region.

In the solid-state imaging device according to the embodiment of the disclosure, in a back side illumination type of solid-state imaging device, since the light-blocking wiring which is formed on the front surface side of the substrate blocks light in at least a portion of the photodiode region, diffuse reflecting of light which is transmitted through the substrate is prevented in the wiring layer. In addition, a predetermined voltage is supplied to the photodiode region of the substrate from the light-blocking wiring via the connection portion. Due to this, the potential of the photodiode region is controlled and suppress of dark current and improvement in transmission efficiency is able to be achieved.

A manufacturing method of a solid-state imaging device according to another embodiment of the disclosure includes the following. First, on a substrate, a photodiode region, which generates a signal charge using photoelectric conversion of light which is incident from a back surface side of the substrate, and an element separation region, which electrically separates adjacent photodiode regions, are formed. Next, an insulting film is formed on a front surface which is a side opposite to a light incidence surface of the substrate. Next, an interlayer insulating film which configures a wiring layer is formed on the insulating film. Next, a connection hole which does not penetrate through the insulating film is formed in the interlayer insulating film on the photodiode region which is formed on the substrate and a connection portion is formed by a conductive material being filled into the connection hole. Next, wiring which configures a wiring layer is formed on the interlayer insulating film and light-blocking wiring, which is connected to the connection portion and covers at least a portion of the photodiode region, is formed.

In the manufacturing method of a solid-state imaging device according to the other embodiment, in a back side illumination type of solid-state imaging device, the light-blocking wiring, which covers at least a portion of the photodiode region which is formed on the substrate, is formed when forming the wiring layer which is formed on the front surface side of the substrate. Due to this, the light-blocking wiring is formed at the same time as the forming of the wiring of the wiring layer. In addition, since the connection portion which connects the substrate and the light-blocking wiring connects via the insulating layer on the photodiode region of the substrate, it is possible to control the potential of the photodiode region in a case where a predetermined voltage is supplied from the light-blocking wiring.

An electronic apparatus according to still another embodiment of the disclosure is provided with an optical lens, a solid-state imaging device which is irradiated with light focused by the optical lens, and a signal processing circuit which processes an output signal which is output from the solid-state imaging device. The solid-state imaging device is provided with a substrate, a photodiode region which is formed on the substrate, a wiring layer, a light-blocking wiring, and a connection portion. The photodiode is formed in the substrate and generates a signal charge using photoelectric conversion of light which is incident from a back surface side of the substrate. The wiring layer is formed on a front surface side of the substrate which is a side opposite to a light incidence surface. The light-blocking wiring is formed in the wiring layer and is formed in a region which covers at least a portion of the photodiode region. The connection portion supplies a predetermined voltage from the light-blocking wiring to the photodiode region.

According to the embodiments of the disclosure, in a back side illumination type of solid-state imaging device, color mixing due to light which is transmitted through the substrate is prevented and suppress of dark current is able to be achieved. In addition, by using the solid-state imaging device, it is possible to obtain an electronic apparatus which is able to improve image quality.

### BRIEF DESCRIPTION OF THE DRAWINGS

FIG. 1 is an outline configuration diagram illustrating an entirety of a solid-state imaging device according to a first embodiment of the disclosure;

FIG. 2 is an example of an equivalence circuit in a unit of a pixel in the solid-state imaging device according to the first embodiment of the disclosure;

FIG. 3 is planar configuration diagram of main portions in a unit of a pixel in the solid-state imaging device according to the first embodiment of the disclosure;

FIG. 4 is a cross-sectional configuration diagram along a line IV-IV of FIG. 3;

FIGS. 5A and 5B are manufacturing process diagrams (first thereof) illustrating a manufacturing method of the solid-state imaging device according to the first embodiment of the disclosure;

FIGS. 6A and 6B are manufacturing process diagrams (second thereof) illustrating a manufacturing method of the solid-state imaging device according to the first embodiment of the disclosure;

FIGS. 7A and 7B are manufacturing process diagrams (third thereof) illustrating a manufacturing method of the solid-state imaging device according to the first embodiment of the disclosure;

FIGS. 8A and 8B are manufacturing process diagrams (fourth thereof) illustrating a manufacturing method of the solid-state imaging device according to the first embodiment of the disclosure;

FIG. 9 is a manufacturing process diagram (fifth thereof) illustrating a manufacturing method of the solid-state imaging device according to the first embodiment of the disclosure;

FIG. 10A is a planar configuration diagram of main portions in a unit of a pixel in a solid-state imaging device according to a second embodiment of the disclosure;

FIG. 10B is an outline cross-sectional configuration diagram along a line XB-XB in FIG. 10A;

FIG. 11A is a planar configuration diagram of main portions in a unit of a pixel in a solid-state imaging device according to a third embodiment of the disclosure;

FIG. 11B is an outline cross-sectional configuration diagram along a line XIB-XIB in FIG. 10A;

FIG. 12 is an overall configuration diagram of a solid-state imaging device according to a fourth embodiment of the disclosure;

FIG. 13 is a cross-sectional configuration diagram of main portions in a unit of a pixel in the solid-state imaging device according to the fourth embodiment of the disclosure; and

FIG. 14 is an outline cross-sectional configuration diagram of an electronic apparatus according to a fifth embodiment of the disclosure.

### DETAILED DESCRIPTION OF EMBODIMENTS

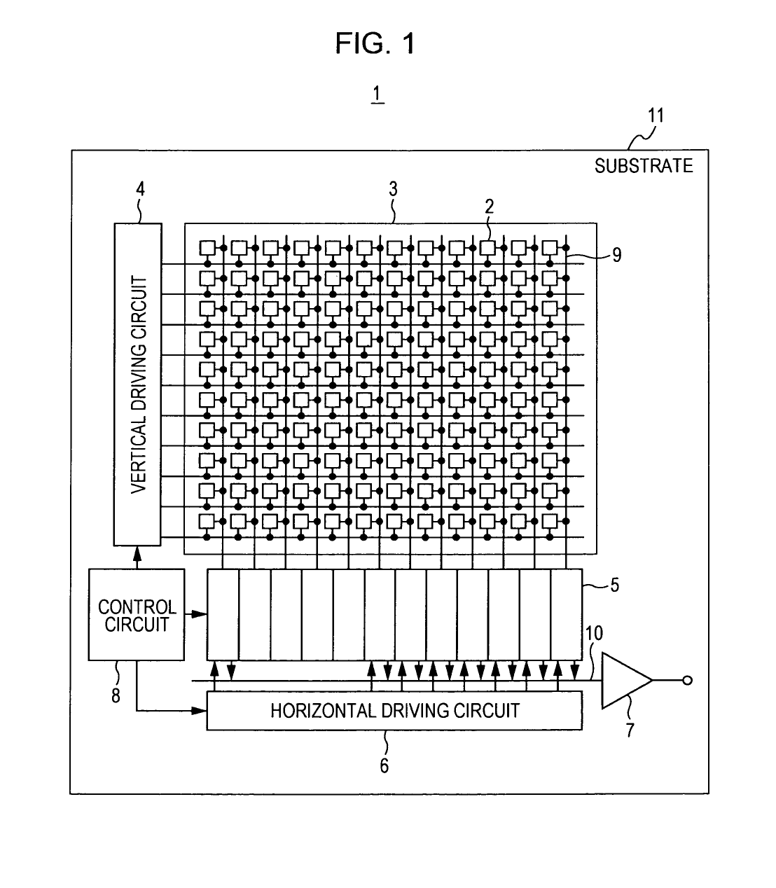

Below, solid-state imaging devices according to the embodiments of the disclosure and an example of an electronic apparatus will be described while referencing FIGS. 1 to 14. The embodiments of the disclosure will be described in the order below. Here, the disclosure is not limited to the examples below.

1. First Embodiment: Example of CMOS Type of Back Side Illumination Solid-state Imaging Device
1-1 Overall Configuration
1-2 Configuration of Main Portions
1-3 Manufacturing Method

2. Second Embodiment: Example of CMOS Type of Back Side Illumination Solid-state Imaging Device

3. Third Embodiment: Example of CMOS Type of Back Side Illumination Solid-state Imaging Device

4. Fourth Embodiment: Example of CCD Type of Back Side Illumination Solid-state Imaging Device
4-1 Overall Configuration
4-2 Configuration of Main Portions

5. Fifth Embodiment: Electronic Apparatus

### 1. First Embodiment: Example of CMOS Type of Back Side Illumination Solid-State Imaging Device

A solid-state imaging device according to a first embodiment of the disclosure will be described. The embodiment uses a CMOS type of back side illumination solid-state imaging device as an example.

[1-1 Overall Configuration]

First, before description of the mina portions, the overall configuration of the solid-state imaging device of the embodiment will be described. FIG. 1 is an outline configuration diagram illustrating an entirety of a solid-state imaging device according to the embodiment.

A solid-state imaging device 1 is configured so as to be provided with a substrate 11 formed from silicon, an imaging region 3 formed from a plurality of pixels 2, a vertical driving circuit 4, a column signal processing circuit 5, a horizontal driving circuit 6, an output circuit 7, a control circuit 8, and the like as shown in FIG. 1.

The pixel 2 is configured from a reception section formed from a photodiode which generates a signal charge according to the amount of light which is received and a plurality of MOS transistors for reading and transferring the signal charge and the plurality of pixels 2 are arranged on the substrate 11 in a regular manner in a two-dimensional array format.

The imaging region 3 is configured from the pixel 2 which are arranged in a plurality in a regular manner in a two-dimensional array format. Then, the imaging region 3 is configured from an effective pixel region which actually receives light and is able to accumulate the signal charge which is generated using photoelectric conversion and a black standard pixel region which is formed in the vicinity of the effective pixel region and which is for outputting an optical black which is the standard for the black level.

The control circuit 8 generates a clock signal, a control signal, and the like, which are the basis for the operation of the vertical driving circuit 4, the column signal processing circuit 5, and the horizontal driving circuit 6, based on a vertical synchronization signal, a horizontal synchronization signal, and a master clock. Then, the clock signal, the control signal, and the like which are generated by the control circuit 8 are input to the vertical driving circuit 4, the column signal processing circuit 5, the horizontal driving circuit 6, and the like.

The vertical driving circuit 4 is configured by, for example, a shift register and selects and scans each of the pixels 2 in the imaging region 3 in units of rows sequentially in the vertical direction. Then, the image signal, which is based on the signal charge generated in the photoelectric conversion elements of each of the pixels 2, is supplied to the column signal processing circuit 5 via a vertical signal line 9.

The column signal processing circuits 5 are, for example, arranged for each row of the pixels 2 and perform signal processing such as noise removal or signal amplification of a signal output from one row of the pixels 2 for each row of pixels using a signal from the black standard pixel region (which is formed in the vicinity of the effective pixel region but not shown). In the output stage of the column signal processing circuits 5, a horizontal selection switch (not shown) is provided between the column signal processing circuits 5 and the horizontal signal line 10.

The horizontal driving circuit 6 is configured by, for example, a shift register, selects each of the column signal processing circuits 5 in order using the sequential output of a horizontal scanning pulse and the image signal from each of the column signal processing circuits 5 is output to the horizontal signal line 10.

The output circuit 7 performs and outputs signal processing with regard to the image signal which is sequentially supplied from each of the column signal processing circuits 5 via the horizontal signal line 10.

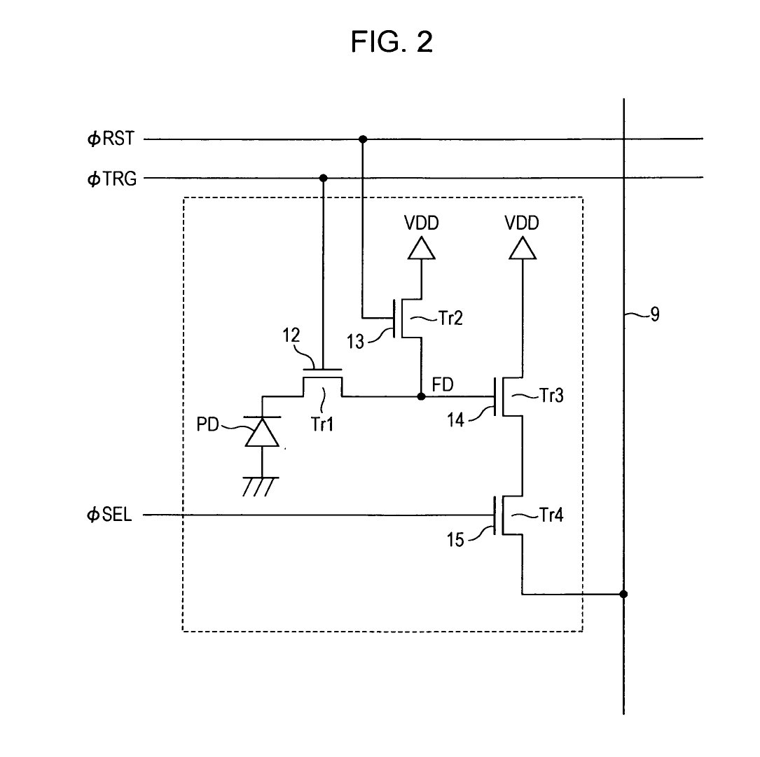

Next, a circuit configuration of each pixel of the embodiment will be described. FIG. 2 is an example of an equivalence circuit in a unit of a pixel in the solid-state imaging device according to the embodiment.

The unit of the pixel 2 in the solid-state imaging device according to the embodiment has a photodiode PD which is a photoelectric conversion element and four transistors of a transfer transistor Tr1, a reset transistor Tr2, an amplification transistor Tr3, and a selection transistor Tr4. The pixel transistors Tr1-Tr4 are configured by n-channel MOS transistors in the embodiment.

The source of the transfer transistor Tr1 is connected to the cathode side of the photodiode PD and the drain of the transfer transistor Tr1 is connected to a floating diffusion region FD. In addition, a transfer wiring which supplies a transfer pulse φ TRG is connected in a gate electrode 12 between the source and the drain of the transfer transistor Tr1. The signal charge (electrons in the embodiment), which is photo-electrically converted by the photodiode PD and accumulated in the photodiode PD, is transferred to the floating diffusion region FD by applying the transfer pulse φ TRG to the gate electrode 12 of the transfer transistor Tr1.

The drain of the reset transistor Tr2 is connected to a power source voltage VDD and the source of the reset transistor Tr2 is connected to the floating diffusion region FD. In addition, a reset wiring which supplies a reset pulse φ RST is connected in a gate electrode 13 between the source and the drain of the reset transistor Tr2. Before the transfer of the signal charge from the photodiode PD to the floating diffusion region FD, the reset pulse φ RST is applied to the gate electrode 13 of the reset transistor Tr2. Due to this, the potential of the floating diffusion region FD is reset to a VDD level using the power source voltage VDD.

The drain of the amplification transistor Tr3 is connected to the power source voltage VDD and the source of the amplification transistor Tr3 is connected to the drain of the selection transistor Tr4. Then, the floating diffusion region FD is connected in a gate electrode 14 between the source and the drain of the amplification transistor Tr3. The amplification transistor Tr3 is configured by a source follower circuit which the power source voltage VDD is set as the load and outputs the image signal according to the change in potential of the floating diffusion region FD.

The drain of the selection transistor Tr4 is connected to the source of the amplification transistor Tr3 and the drain of the selection transistor Tr4 is connected to the vertical signal line. In addition, a selection wiring which supplies a selection pulse φ SEL is connected in a gate electrode 15 between the source and the drain of the selection transistor Tr4. The image signal which is amplified by the amplification transistor Tr3 is output to the vertical signal line 9 by the selection pulse φ SEL being supplied to the gate electrode 15 for each pixel.

In the solid-state imaging device 1 which has the configuration above, the signal charge which is accumulated in the photodiode PD by the transfer pulse φ TRG being supplied to the gate electrode 12 is read out to the floating diffusion region FD using the transfer transistor Tr1. The potential of the floating diffusion region FD changes due to the reading out of the signal charge and the change in potential is transferred to the gate electrode 14. Then, the potential supplied to the gate electrode 14 is amplified by the amplification transistor Tr3 and is selectively output as the image signal to the vertical signal line 9 using the selection transistor Tr4. In addition, by the reset pulse φ RST being supplied to the gate electrode 13, the signal charge which is read out to the floating diffusion region FD is reset so as to be the same potential as the potential in the vicinity of the power source voltage VDD using the reset transistor Tr2.

Then, the image signal which is output to the vertical signal line 9 is output via the column signal processing circuit 5, the horizontal signal line 10 and the output circuit 7 as shown in FIG. 1.

The example in FIG. 2 is an example where four pixel transistors are used but there may be a configuration using three transistors where the selection transistor Tr4 is excluded. In addition, the example in FIG. 2 is an example where four pixel transistors are used in each of the pixels, but there may be an example where pixel transistors are shared between a plurality of pixels.

[1-2 Configuration of Main Portions]

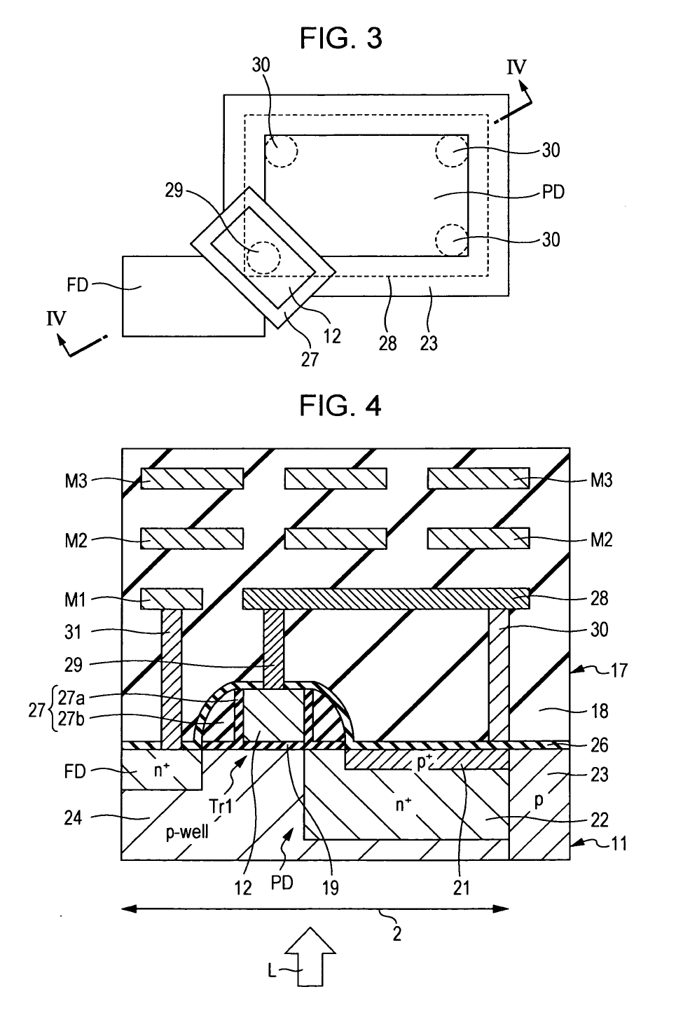

Based on the overall configuration described above, a configuration of main portions of the solid-state imaging device of the embodiment will be described. FIG. 3 is planar configuration diagram of the main portions in a unit of a pixel of the embodiment, and FIG. 4 is an outline cross-sectional configuration diagram along a line IV-IV of FIG. 3. In addition, in the description below, a region where the photodiode is formed is described as a “photodiode region PD” and a region where the floating diffusion is formed is described as a “floating diffusion region FD”.

The solid-state imaging device of the embodiment is configured to have the photodiode region PD, the substrate 11 where the transfer transistor Tr1 which reads out the signal charge generated by the photodiode region PD is formed, and a wiring layer 17 which is formed on a front surface side of the substrate 11 as shown in FIG. 4. In addition, a light-blocking wiring 28 and a connection portion 30 are provided in the wiring layer 17.

The substrate 11 is configured by a first conductive type (n-type in the embodiment) of semiconductor substrate formed from silicon and a p-type well region, where a second conductive type (p-type in the embodiment) of impurities are formed using ion implantation, is formed on the front surface side. The respective pixels 2 are formed in the p-type well regions.

The photodiode region PD is configured by a dark current suppressing region 21 formed from a p-type impurities region with a high concentration which is formed on the front surface side of the substrate 11 and a charge accumulation region 22 formed from a n-type impurities region which is formed at a lower portion of the dark current suppressing region 21. In the photodiode region PD, mainly, a photodiode is configured by the pn junction between the dark current suppressing region 21 and the charge accumulation region 22 formed to be in contact with the dark current suppressing region 21. In the photodiode region PD, signal charge is generated and accumulated according to the amount of light which incident. In addition, dark current is suppressed by pinning the electrons which are the source of the dark current generated at the boundary surface of the substrate 11 in a positive hole which is a majority carrier of the dark current suppressing region 21. In addition, an element separating region 23 where p-type impurities are formed using ion implantation is formed in a region which surrounds the photodiode region PD, and due to the element separating region 23, the photodiode regions PD between the pixels 2 are electrically separated.

The transfer transistor Tr1 is configured from the floating diffusion region FD which is a charge read-out region and the gate electrode 12 which is a charge read-out electrode. The floating diffusion region FD is formed from an n-type impurities region with a high concentration which is formed on the front surface side of the substrate 11 and is formed in a region adjacent to the photodiode PD.

The gate electrode 12 is formed on the front surface of the substrate 11 between the photodiode region PD and the floating diffusion region FD via a gate insulating film 19, and for example, is configured by polysilicon. In addition, a side wall 27 formed from a first insulating layer 27a and a second insulating layer 27b is formed in a side portion of the gate electrode 12.

Here, the dark current suppressing region 21 which configures the photodiode region PD is not formed up to directly below the side wall 27 and the charge accumulation region 22 is formed so as to extend until the region directly below the side wall 27. As a result, since the front surface of the substrate 11 directly below the side wall 27 is the charge accumulation region 22, improvement of transfer efficiently is able to be achieved without hindering the transfer of charge to the dark current suppressing region 21 which is formed from the p-type impurities region in a case where a transfer voltage is applied to the gate electrode 12.

In addition, as described above, transistors other than the reset transistor, the amplification transistor, the selection transistor, and the like are formed for each pixel, but are omitted from the diagrams in FIGS. 3 and 4.

The wiring layer 17 is form on the front surface side of the substrate 11 and is configured to have wirings M1, M2, and M3 which are laminated in a plurality of layers (three layers in the embodiment) via an interlayer insulating film 18. Each of the wirings M1, M2, and M3 are configured by a metallic material such as copper or aluminum. In addition, the light-blocking wiring 28 is configured by the wiring M1 which is the bottom layer, that is, the wiring M1 which is on a side closest to the substrate 11.

The light-blocking wiring 28 is formed for each pixel 2 and is formed in a region which covers the entire photodiode region PD of each of the pixels 2, and a portion of the light-blocking wiring 28 is formed so as to extend until an upper portion of the gate electrode 12 of the transfer transistor Tr1. The light-blocking wiring 28 is configured by a metallic material which has light blocking characteristics, and in the embodiment, is formed by the same metallic material as the wiring M1 which is the first layer in the wiring layer 17. Then, the light-blocking wiring 28 is electrically connected to the gate electrode 12 of the transfer transistor Tr1 via a contact portion 29 which is formed in the interlayer insulating film 18 and is connected to the connection portion 30 which is formed in the same interlayer insulating film 18.

The connection portion 30 is formed in the interlayer insulating film 18 between the photodiode region PD formed on the substrate 11 and the light-blocking wiring 28 and is formed so as to be connected to an insulating film 26 which is formed on the substrate 11. The connection portion 30 is formed in a position to cover a portion of the region on the side of the photodiode region PD which is a boundary region of the photodiode region PD formed on the substrate 11 and the element separation region 23. In the embodiment, as shown in FIG. 3, the connection portion 30 is formed in three corners of the photodiode region PD, which is formed in substantially a rectangular shape, excluding the position where the transfer transistor Tr1 is formed. Due to the connection portion 30, a predetermined voltage is supplied to the photodiode region PD from the light-blocking wiring 28, and due to this, the potential of the front surface side of the photodiode region PD is controlled. At this time, since the connection portion 30 is connected via the insulating film 26 on the substrate 11, the photodiode region PD and the connection portion 30 are not electrically connected.

Then, since both the connection portion 30 and the gate electrode 12 of the transfer transistor Tr1 are connected to the light-blocking wiring 28, the voltage which is supplied to the photodiode region PD via the connection portion 30 and the voltage which is supplied to the gate electrode 12 via the contact portion 29 are synchronized.

In FIG. 4, although omitted from the diagram, a color filter layer and an on-chip lens are formed on a back surface side of the substrate 11 in the same manner as a typical back side illumination type of solid-state imaging device. Then, in the solid-state imaging device 1 of the embodiment, there is a configuration where light L is incident from a back surface side of the substrate 11.

[1-3 Manufacturing Method]

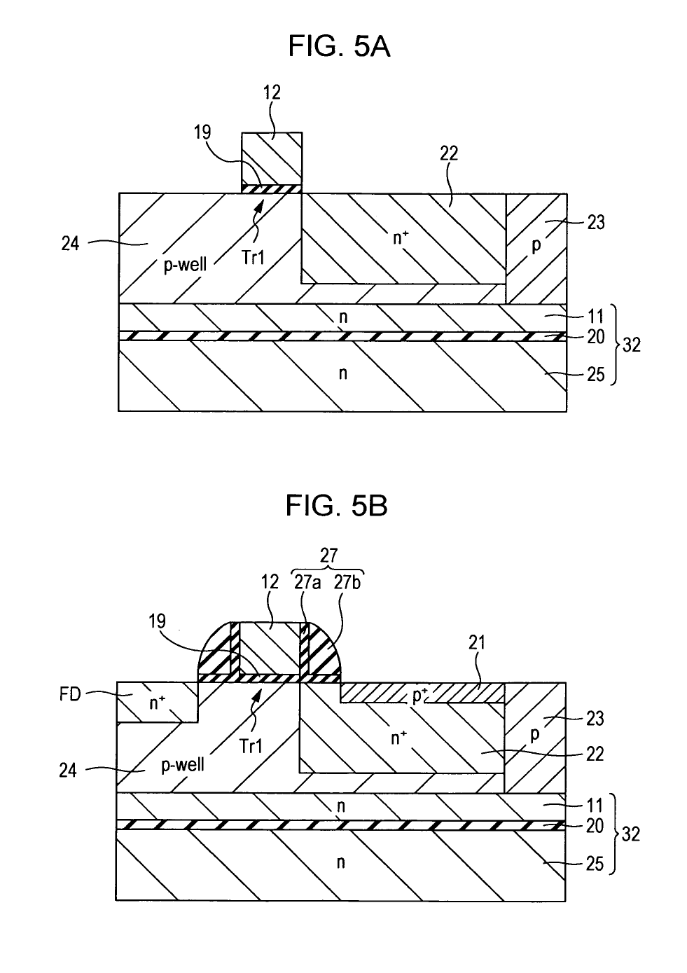

Next, a manufacturing method of the solid-state imaging device 1 of the embodiment will be described. FIGS. 5A to 9 are process diagrams illustrating a manufacturing method of the solid-state imaging device 1 of the embodiment.

First, as shown in FIG. 5A, an SOI substrate 32 is prepared by laminating the substrate 11 formed from an n-type semiconductor layer, a silicon oxide film 20, and a substrate 25 formed from an n-type semiconductor layer in this order. Then, a P-well region 24 is formed in the upper layer of the front surface side of the substrate 11 by, for example, boron being ion implanted as the p-type impurities material and by annealing at 1000° C.

Next, ion implanting of, for example, phosphorus as the n-type impurities material is performed in the P-well region 24 at a higher concentration than the concentration of the n-type impurities of the substrate 11. Due to this, an n-type impurities region, which is the charge accumulation region 22 which configures the photodiode region PD, is formed. Furthermore, a p-type impurities region which is the element separation region 23 is formed by ion implanting of, for example, boron between the adjacent photodiode regions PD. The concentration of impurities in the element separation region 23 is set so that the potential is substantially the same as that of the P-well region 24 when a substrate potential is applied to the substrate 11. Then, the charge accumulation region 22 and the element separation region 23 are formed by an annealing process at 1000° C.

After that, after forming the gate insulating film 19 formed from, for example, silicon oxide on the front surface of the substrate 11, a polysilicon material layer is deposited using a CVD (Chemical Vapor Deposition) method. After that, in the patterning of the floating diffusion, the gate electrode 12 of the transfer transistor Tr1 is formed in a region between the photodiode region PD and the floating diffusion region FD. At this time, the gate insulating film 19 which is exposed on the substrate 11 other than the lower portion of the gate electrode 12 is removed.

Next, as shown in FIG. 5B, the side wall 27 is formed on a side portion of the gate electrode 12. The side wall 27 is formed by, for example, an LP-TEOS film being deposited as the first insulating layer 27a which is the first layer with a thickness of 10 nm to 100 nm, an LP-SiN film being deposited as the second layer of the second insulating layer 27b with a thickness of 10 nm to 100 nm, and dry etching being performed using a CF4 gas. After the formation of the side wall 27, the floating diffusion region FD and the dark current suppressing region 21 are formed with the side wall 27 as a mask on the transfer transistor Tr1 side by phosphorus which is an n-type impurity being ion implanted on an opposite side via a gate electrode of the charge accumulation region 22, boron which is a p-type impurity being ion implanted on the front side surface of the charge accumulation region 22 with a higher concentration than the p-type well region 24, and annealing at 1000° C.

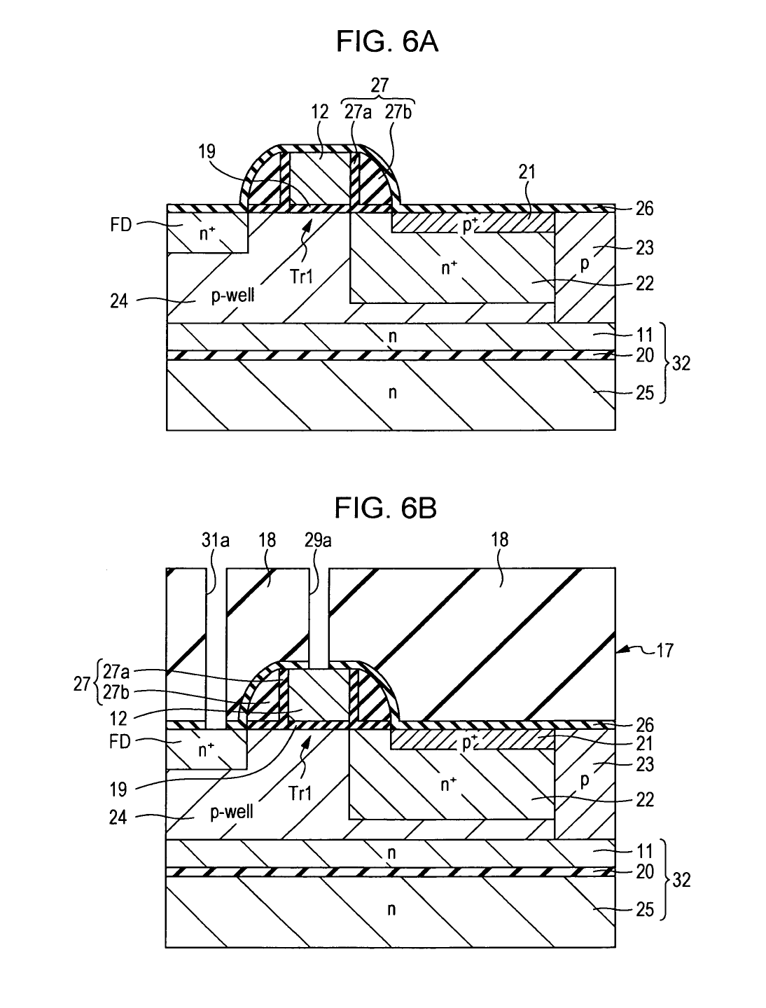

Next, as shown in FIG. 6A, the insulating film 26 formed from a silicide block film is formed on the entire surface of the front surface of the substrate 11 which includes the gate electrode 12. The insulating film 26 formed from a silicide block film is formed by, for example, a LP-TEOS film with a thickness of 10 nm to 30 nm being deposited and a LP-SiN film with a thickness of 10 nm to 30 nm being deposited. Although not shown in FIG. 6A, in the vicinity of the transistor region, a Co silicide film is formed by removing the silicide block film by dry etching using a CF4 gas and performing, for example, Co sputtering and annealing. In the embodiment, the insulating film 26 is deposited using the silicide block film described above, but it is possible to form an insulating film other than the silicide block film. In addition, a portion of the side wall 27 which was formed at an earlier stage remains on the substrate 11 and it is possible for this to be used as an insulating film.

Next, as shown in FIG. 6B, for example, an NSG film is deposited on the insulating film 26 as the first layer of the interlayer insulating film 18 with a thickness of 400 nm to 700 nm. After that, the front surface of the interlayer insulating film 18 is smoothened using a CMP (Chemical Mechanical Polishing), and contact holes 29a and 31a are formed as contact portions 29 and 31 in the interlayer insulating film 18 on the floating diffusion region FD and an upper portion of the gate electrode 12 of the transfer transistor Tr1. The contact holes 29a and 31a are formed at the same time as contact holes formed in the vicinity of the transistor region and are formed using lithography or etching. Here, the contact portion 31 which is formed in an upper portion of the floating diffusion region FD comes into electrically contact with the wirings of either of the floating diffusion region FD formed on the substrate 11 or the wiring layer 17. In addition, the contact portion 29 which is formed in an upper portion of the gate electrode 12 of the transfer transistor Tr1 comes into electrically contact with the wirings of either of the gate electrode 12 and the wiring layer 17. As a result, the contact holes 29a and 31a are formed with an etching condition which penetrates the silicide block film which is the insulating film 26.

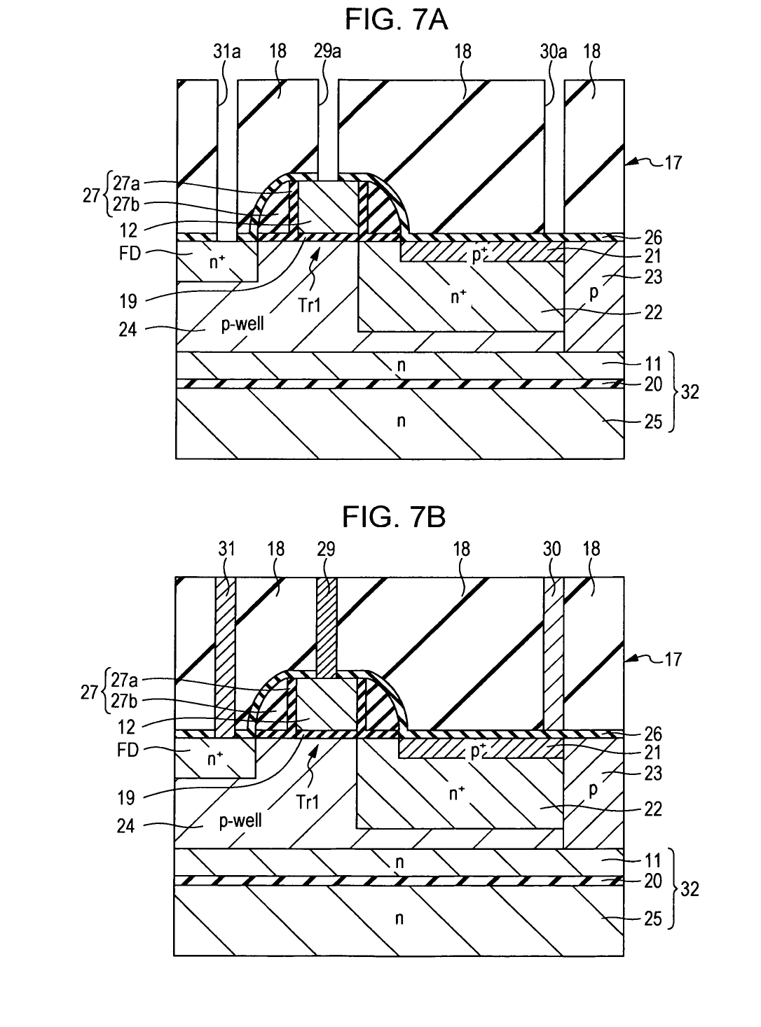

Next, as shown in FIG. 7A, a connection hole 30a for the connection portion 30 is formed using lithography again in a region on the photodiode region PD side which is a region which is a boundary with the photodiode region PD and the element separation region 23. The aim of the connection portion 30 which is formed in a boundary region between the photodiode region PD and the element separation region 23 is to control the potential of the front surface of the substrate 11 in the boundary region between the photodiode region PD and the element separation region 23. As a result, the contact hole 30a is formed with an etching condition where the silicide block film which is the insulating film 26 is not penetrated. An example of the etching condition is a method where the etching of the LP-TEOS film is performed while controlling for time after the etching of the LP-SiN film which is formed on the upper layer of the silicide block film. Other than this, hole formation is possible where the insulating film 26 is not penetrated by controlling the amount of over etching after the detection of the end point in the etching process of the LP-SiN film.

Next, as shown in FIG. 7B, tungsten as a filling material fills in the contact holes 29a and 31a and the connection hole 30a which were formed in the processes in FIGS. 6B and 7A and is smoothened using a CMP method. Due to this, the contact portions 29 and 31 and the connection portion 30 are formed.

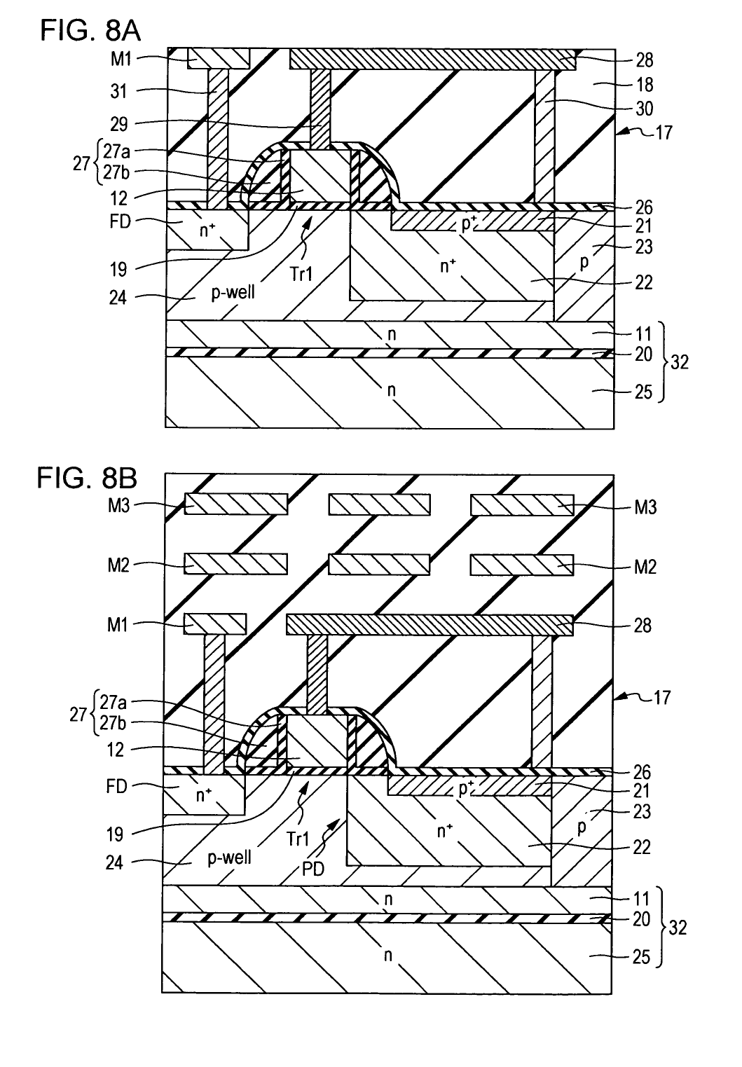

Next, as shown in FIG. 8A, a wiring formed from, for example, copper is formed as the wiring M1 which is the first layer. At this time, a portion of the wiring M1 which is the first layer is formed as the light-blocking wiring 28. The light-blocking wiring 28 is formed so as to cover the entire photodiode region PD and a portion is formed to extend to the gate electrode 12 side of the transfer transistor Tr1. Then, the light-blocking wiring 28 is formed so as to be electrically connected to the contact portion 29 on the gate electrode 12 of the transfer transistor Tr1 and the connection portion 30. In addition, out of the wiring M1 which is the first layer, the wiring M1 which is not connected to the light-blocking wiring 28 is formed so as to be connected to the contact portion 31 in an upper portion of the floating diffusion FD.

After this, by alternately repeating the forming of the interlayer insulating film 18 and the wiring M2 and M3, the wiring layer 17 is formed from the plurality of layers (three layers in the embodiment) of the wirings M1, M2, and M3 as shown in FIG. 8B. At this time, contact portions connect between predetermined wirings.

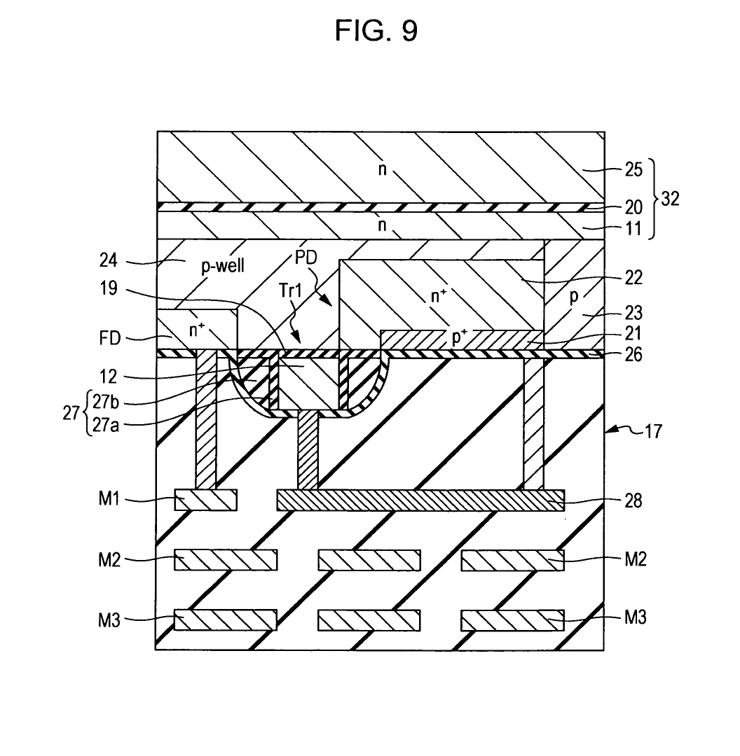

After the formation of the wiring layer 17, a bonding substrate (not shown) formed from, for example, a silicon substrate, is adhered on the wiring layer 17, and as shown in FIG. 9, the SOI substrate 32 is reversed and the substrate 25 where the pixels 2 are not formed and the silicon oxide film 20 is removed using physical polishing. Then, in addition, the back surface side of the substrate 11 is polished and there is the solid-state imaging device 1 with a predetermined thickness as shown in FIG. 4.

After that, by forming a color filter layer and a on-chip lens (not shown) on the back surface side of the substrate 11, the back side illumination type of solid-state imaging device 1 of the embodiment is complete.

In the solid-state imaging device 1 of the embodiment, the light L which is incident from the back surface side of the substrate 11 is photoelectrically converted by the photodiode region PD and the signal charge according to the amount of light is generated and accumulated in the charge accumulation region 22. Then, when accumulating charge, a negative (or ground) potential is supplied from the light-blocking wiring 28 to the gate electrode 12 of the transfer transistor Tr1 and the photodiode region PD. By doing this, the transfer transistor Tr1 is in an off state in the same manner as the driving of a typical solid-state imaging device. On the other hand, by supplying a negative (or ground) potential using the connection portion to the boundary region with the element separation region 23 in the photodiode region PD, there is excitation of the positive holes in the front surface side of the substrate 11. Due to this, a hole pinning effect on the front surface side of the substrate 11 is reinforced and the suppression of dark current is able to be achieved in the photodiode region PD which is connected to the connection portion 30.

After the formation of the gate electrode 12 of the transfer transistor Tr1, the dark current suppressing region 21 is formed using ion implanting via a resist in the element separation region 23 side, but ion implanting is difficult at the edge portions of the resist. As a result, the dark current suppressing region 21 is difficult to form in a portion on the edge of the photodiode region PD and the element separating region 23, that is, at the boundary, and there is a tendency for hole pinning to be excluded from this portion. In the embodiment, since the connection portion 30 is provided in the boundary of the photodiode region PD and the element separation region 23 where it is easy for pinning to be excluded and for dark current to be generated, it is possible to suppress dark current from the boundary of the photodiode region PD and the element separation region 23.

In addition, after accumulating charge, a positive voltage is supplied to the gate electrode 12 of the transfer transistor Tr1 and the photodiode region PD from the light-blocking wiring 28. By doing this, the transfer transistor Tr1 is in an on state in the same manner as the driving of a typical solid-state imaging device and the charge signal accumulated in the charge accumulation region 22 is read out to the floating diffusion region FD. On the other hand, by supplying a positive voltage using the connection portion 30 to the boundary region with the element separation region 23 in the photodiode region PD, there is excitation of electrons in the front surface side of the substrate 11. Due to this, read-out efficiency is improved and an effect of suppressing residual images is able to be achieved.

In addition, in the solid-state imaging device 1 of the embodiment, the photodiode region PD in the front surface side of the substrate 11 is covered by the light-blocking wiring 28. Due to this, since the transmitted light which is incident from the back side surface of the substrate 11 and is transmitted through the substrate 11 is blocked by the light-blocking wiring 28 which is formed using the wiring M1 which is the bottom layer, it is possible to prevent diffuse reflecting of the transmitted light between the wirings without the transmitted light reaching the wiring M3 which is the upper layer. Due to this, improvement of color mixing is able to be achieved. In particular, improvement of color mixing is able to be achieved with regard to red light which has a long wavelength and tends to be transmitted through the substrate 11.

The solid-state imaging device 1 of the embodiment is an example where the connection portion 30 is formed in the photodiode region PD side which is a boundary region of the photodiode region PD and the element separating region 23. However, the solid-state imaging device 1 of the embodiment is not limited to this and it is sufficient if the connection portion 30 is formed at least at an edge of the photodiode region PD and may be formed to slightly protrude to the element separation region 23 side. In a case where the connection portion 30 is formed to protrude to the element separation region 23 side, since the negative voltage is able to be supplied also to the element separation region 23 when accumulating charge, improvement in separation capabilities is able to be achieved and suppressing of blooming is able to be achieved.

In addition, the solid-state imaging device 1 of the embodiment is an example where the voltage for controlling the potential of the photodiode region PD is synchronized with the voltage which is applied to the gate electrode 12 of the transfer transistor Tr1, but the voltages may be driven individually without being synchronized. Furthermore, in the embodiment, the connection portion 30 is formed in the boundary region of the photodiode region PD and the element separating region 23, but in addition, the connection portion 30 may be provided in a central portion of the photodiode region PD.

Here, the embodiment is an example where the element separation region 23 formed using ion implanting of p-type impurities is used as a layer which separates the photodiode regions PD of the adjacent pixels 2, but the configuration of the element separation region 23 is not limited to this. For example, the disclosure is able to be applied in a case where an STI (Shallow Trench Isolation) is used to separate the photodiode regions PD. In addition, the disclosure is able to be applied also to a configuration where the pixel transistors are shared by a plurality of pixels 2.

### 2. Second Embodiment: Example of CMOS Type of Back Side Illumination Solid-State Imaging Device

Next, a solid-state imaging device according to a second embodiment of the disclosure will be described. The entire configuration of the solid-state imaging device of the embodiment and a circuit configuration of each pixel is the same as the first embodiment, and thus, overlapping description is omitted.

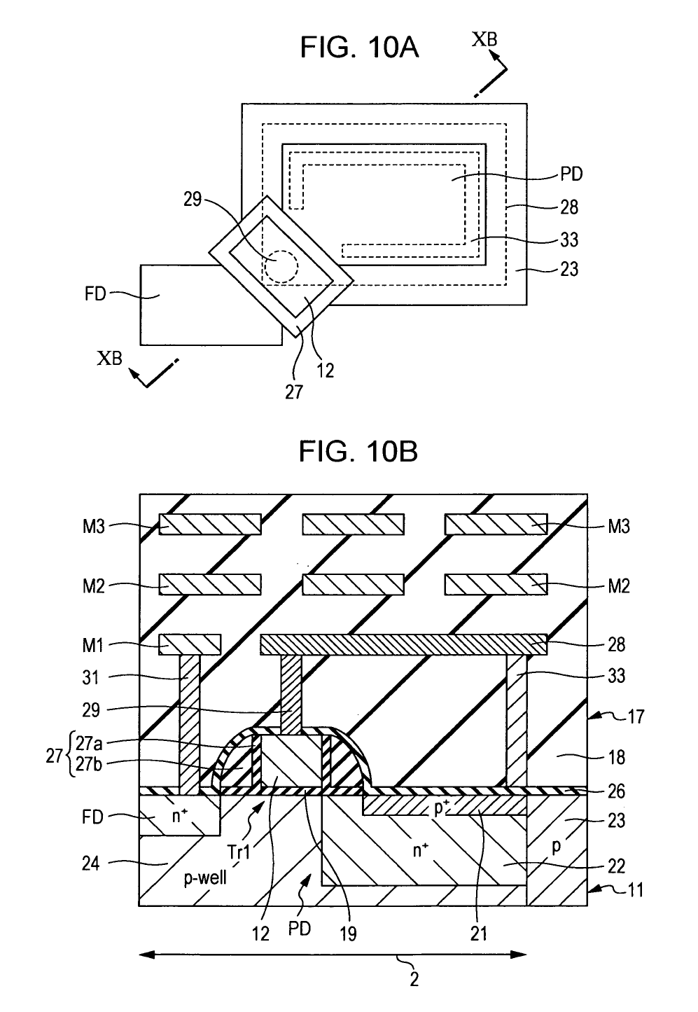

FIG. 10A is a planar configuration diagram of main portions in a unit of a pixel of the embodiment, and FIG. 10B is an outline cross-sectional configuration diagram along a line XB-XB in FIG. 10A. In FIGS. 10A and 10B, portions which correspond to FIGS. 3 and 4 have the same reference numeral attached and overlapping description is omitted. The solid-state imaging device of the embodiment is an example where the configuration of the connection portion partially differs to the first embodiment.

In the solid-state imaging device of the embodiment, as shown in FIG. 10A, a connection portion 33 is formed on the photodiode region PD side in a boundary region of the photodiode region PD and the element separation region 23 and is formed to surround the photodiode region PD.

The connection portion 33 of the embodiment is also able to be formed by the same process as the first embodiment. In this case, in the process of FIG. 7A, a connection hole which is continuous around the photodiode region PD is formed using etching in a region where the connection portion is to be formed, and in the process of FIG. 7B, it is possible to form the connection portion by filling in the connection hole.

In the solid-state imaging device of the embodiment, since the connection portion 33 is formed to surround the photodiode region PD, the connection portion 33 itself functions as a light blocking wall for preventing the incidence of light which is transmitted through the substrate 11 on adjacent pixels. In addition, in the solid-state imaging device of the embodiment, the boundary region of the photodiode region PD and the element separation region 23 is completely surrounded by the connection portion 33 and a predetermined voltage is supplied to the boundary region. As a result, in a case where a positive voltage is supplied from the light-blocking wiring 28 and the signal charge is transferred, it is possible to further improve the transfer efficiency. Then, in the embodiment, it is possible to obtain the same effects as the first embodiment.

### 3. Third Embodiment: Example of CMOS Type of Back Side Illumination Solid-State Imaging Device

Next, a solid-state imaging device according to a third embodiment of the disclosure will be described. The entire configuration of the solid-state imaging device of the embodiment and a circuit configuration of each pixel is the same as the first embodiment, and thus, overlapping description is omitted.

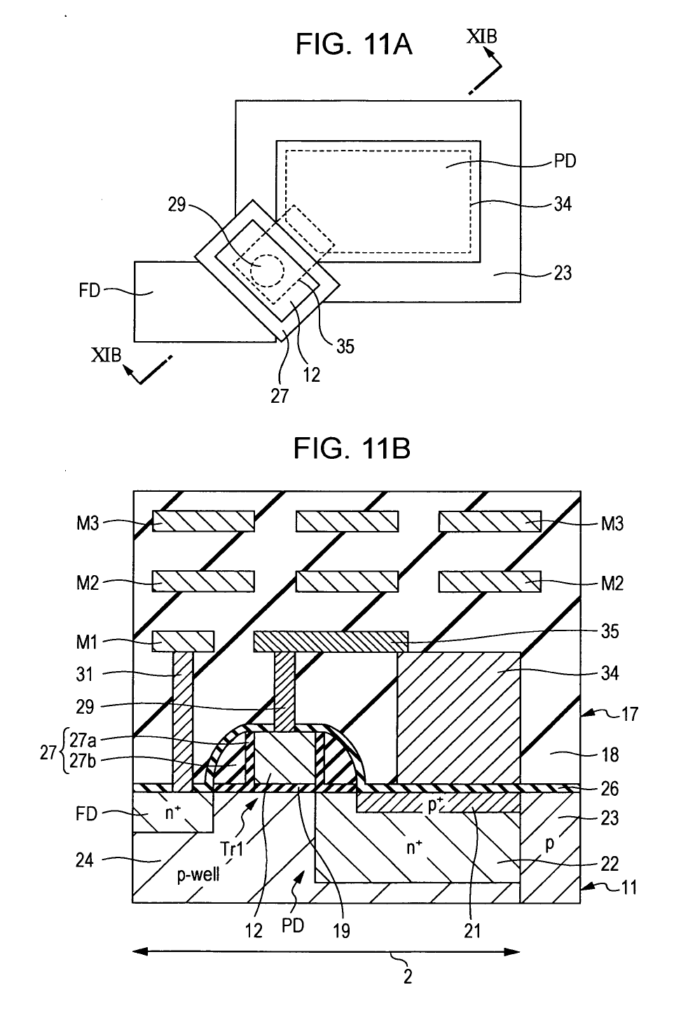

FIG. 11A is a planar configuration diagram of main portions in a unit of a pixel of the embodiment, and FIG. 11B is an outline cross-sectional configuration diagram along a line XIB-XIB in FIG. 11A. In FIGS. 11A and 11B, portions which correspond to FIGS. 3 and 4 have the same reference numeral attached and overlapping description is omitted. The solid-state imaging device of the embodiment is an example where the configuration of the connection portion and the light-blocking wiring partially differ to the first embodiment.

In the solid-state imaging device of the embodiment, as shown in FIG. 11A, a connection portion 34 is formed in a region which is covered by the entirety of the photodiode region PD within a range which does not come into contact with the transfer transistor Tr1.

The connection portion 34 of the embodiment is also able to be formed by the same process as the first embodiment. In this case, in the process of FIG. 7A, a connection hole with a predetermined size is formed in a region on an upper portion of the photodiode region PD using etching in a region where the connection portion is to be formed, and in the process of FIG. 7B, it is possible to form the connection portion by filling in the connection hole.

In the embodiment, it is possible to supply a predetermined potential from the connection portion 34 over the entirety of one the photodiode region PD. Due to this, hole pinning is reinforced over the entirety of the photodiode region PD when accumulating charge, and in addition, improvement in transfer efficiency when transferring is able to be achieved.

In addition, in the embodiment, since the connection portion 34 itself is covered by the entirety of the photodiode region PD, the connection portion 34 acts as a light block. In this case, it is sufficient if a light-blocking wiring 35, which is formed using the wiring M1 which is the bottom layer, is able to block light to the photodiode region PD which is not able to be blocked by the connection portion 34 and is formed so as to come into contact with the contact portion 29 on the gate electrode 12 of the transfer transistor Tr1. As a result, since it is possible to form the light-blocking wiring 35 with a smaller area, the degree of freedom of the wiring layout is improved. Otherwise, it is possible to obtain the same effects as the first embodiment.

### 4. Fourth Embodiment: Example of CCD Type of Back Side Illumination Solid-State Imaging Device

Next, a solid-state imaging device according to a fourth embodiment of the disclosure will be described. The embodiment is an example of a CCD Type of back side illumination solid-state imaging device.

[4-1 Overall Configuration]

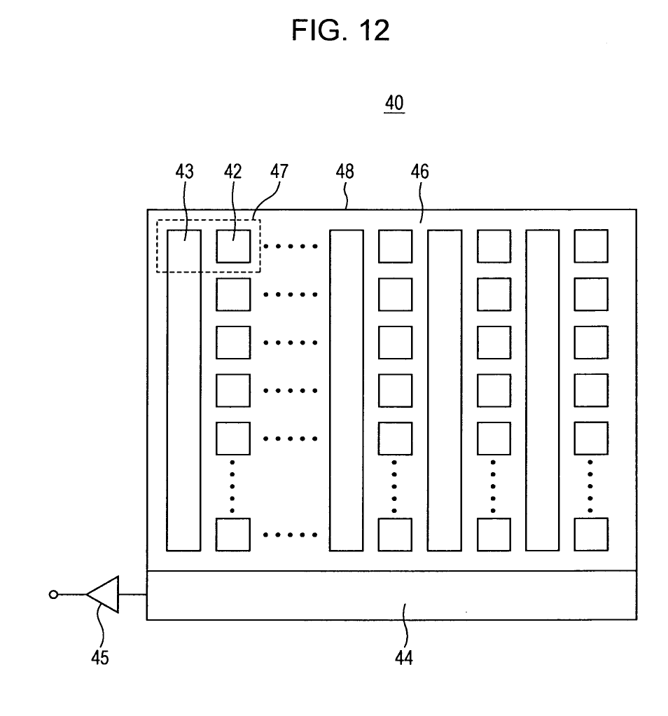

First, before the description of the configuration of the main portions, the entire configuration of the solid-state imaging device of the embodiment will be described. FIG. 12 is an overall configuration diagram of a solid-state imaging device 40 according to the embodiment. As shown in FIG. 12, the solid-state imaging device 40 of the embodiment is configured to have a plurality of reception sections 42 formed from a photodiode on a substrate 48, a vertical transfer register 43, a horizontal transfer register 44, and a output circuit 45. Then, a unit of a pixel 47 is configured by one of the reception sections 42 and the vertical transfer register 43 which is adjacent to the reception section 42. In addition, a region where a plurality of the pixels 47 are formed is a pixel section 46.

The reception section 42 is configured by a photodiode and a plurality are formed in a matrix format in the horizontal direction and the vertical direction of the substrate 48. In the reception section 42, signal charge is generated and accumulated in accordance with incident light using photoelectric conversion.

The vertical transfer register 43 has a CCD configuration and a plurality are formed in the vertical direction for each of the reception sections 42 which are arranged in the vertical direction. The vertical transfer register 43 reads out the signal charge accumulated in the reception section 42 and transfers the signal charge in the vertical direction. A transfer stage where the vertical transfer register 43 of the embodiment is formed is configured to be driven in, for example, four phases, by a transfer pulse which is applied from a transfer driving pulse circuit (not shown). In addition, at a final stage of the vertical transfer register 43, there is a configuration where the signal charge which is held at the final stage by the transfer pulse being applied is transferred to the horizontal transfer register 44.

The horizontal transfer register 44 has a CCD configuration and is formed at one end of the final stage of the vertical transfer register 43. In the transfer stage where the horizontal transfer register 44 is formed, the charge signal which has been vertically transferred using the vertical transfer register 43 is transferred in the horizontal direction for each signal horizontal line.

The output circuit 45 is formed at the final stage of the horizontal transfer register 44. In the output circuit 45, the charge signal which has been horizontally transferred using the horizontal transfer register 44 is output as a video signal using charge-voltage conversion.

Using the solid-state imaging device 40 which has the configuration above, the signal charge which is generated and accumulated using the reception section 42 is transferred in the vertical direction using the vertical transfer register 43 and is transferred in the horizontal transfer register 44. Then, the signal charge which is transferred in the horizontal transfer register 44 is transferred in the horizontal direction and output as a video signal via the output circuit 45.

[4-2 Configuration of Main Portions]

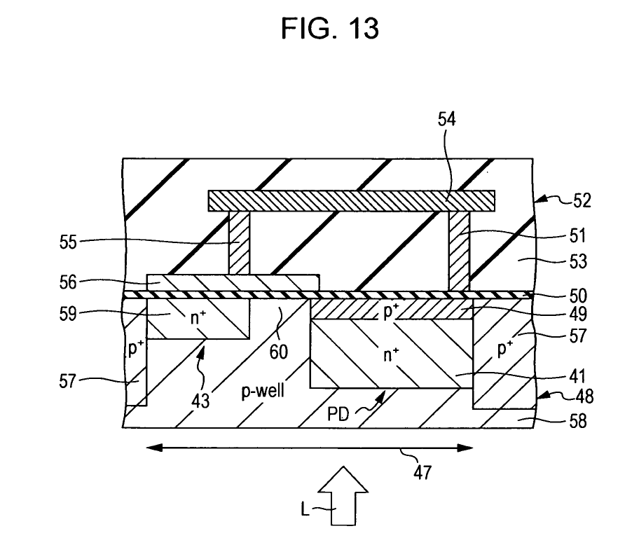

Next, the configuration of the main portions of the solid-state imaging device 40 of the embodiment will be described. FIG. 13 is a cross-sectional configuration diagram of main portions in a unit of a pixel 47 of the embodiment.

The solid-state imaging device 40 of the embodiment is provided with a substrate 48, where the photo diode region PD which configures the reception section and the vertical transfer register 43 which reads out and transfers the signal charge which is generated in the photodiode region PD, and a wiring layer 52 which is formed on the front surface side of the substrate 48. In addition, a light-blocking wiring 54 and a connection portion 51 are provided in the wiring layer 52.

The substrate 48 is configured by a first conductive type (n-type in the embodiment) of semiconductor substrate formed from silicon and a p-type well region 58, where a second conductive type (p-type in the embodiment) of impurities are formed using ion implantation, is formed on the front surface side. The respective pixels 47 are formed in the p-type well regions 58.

The photodiode region PD is configured by a dark current suppressing region 49 formed on the front surface side of the substrate 48 and a charge accumulation region 41 which is formed at a lower portion of the dark current suppressing region 49. The dark current suppressing region 49 is configured by a p-type impurities region with a higher concentration than that of the p-type well region 58. In addition, the charge accumulation region 41 is configured by an n-type impurities region with a higher concentration than the impurities concentration of the substrate 48. In the photodiode region PD, mainly, a photodiode is configured by the pn junction between the dark current suppressing region 49 and the charge accumulation region 41 formed to be in contact with the dark current suppressing region 49. In the photodiode region PD, signal charge is generated according to the amount of light which incident and accumulated in the charge accumulation region 41. In addition, dark current is suppressed by pinning the electrons which are the source of the dark current generated at the boundary surface of the substrate 48 in a positive hole which is a majority carrier of the dark current suppressing region 49.

The vertical transfer register 43 has a CCD configuration and is formed in a region adjacent to the photodiode region PD. The vertical transfer register 43 is configured by a transfer channel portion 59 formed from an n-type impurities region and a region between the transfer channel portion 59 and the reception section 42 is set as a read-out channel portion 60. The signal charge which is generated and accumulated in the photodiode region PD is read out by the transfer channel portion 59 via the read-out channel portion 60 and is transferred in the vertical direction in the transfer channel portion 59. Then, on a side opposite to the read-out channel portion 60 of the photodiode region PD, an element separation region 57 formed from p-type impurities using ion implantation is formed. The adjacent pixels 47 are electrically separated by the element separation region 57.

The wiring layer 52 is configured to include a transfer electrode 56, which is formed in an upper portion of the transfer channel portion 59 and the read-out channel portion 60 of the substrate 48 via a gate insulating film 50, and a interlayer insulating film 53 which is covered by the transfer electrode 56. A plurality of the transfer electrodes 56 are actually formed along the transfer channel portion 59, and in FIG. 13, the transfer electrode 56 is shown to also be used as a read-out electrode which is used when charge signal is read out from the photodiode region PD to the transfer channel portion 59. Then, the light-blocking wiring 54, which supplies a driving pulse to the transfer electrode 56 and covers the photodiode region PD, is formed in the wiring layer 52.

The light-blocking wiring 54 is formed for each of the pixels 47 and is formed in a region which covers all of the photodiode region PD of the respective pixels 47. In addition, a portion of the light-blocking wiring 54 is formed to extend until an upper portion of the transfer electrode 56. The light-blocking wiring 54 is configured by a metallic material which has light blocking characteristics, and in the embodiment, is formed by the same metallic material as the wiring which is the first layer in the wiring layer 52, and for example, is configured by copper, aluminum, or the like. Then, the light-blocking wiring 54 is electrically connected to the transfer electrode 56 via a contact portion 55 which is formed in the interlayer insulating film 53 and is connected to the connection portion 51 which is formed in the same interlayer insulating film 53.

The connection portion 51 is formed in the interlayer insulating film 53 between the photodiode region PD formed on the substrate 48 and the light-blocking wiring 54 and is formed so as to be connected to an insulating film (a gate insulating film 50 in this case) which is formed on the substrate 48. The connection portion 51 is formed on a portion of the photodiode region PD side which is a boundary region of the photodiode region PD formed on the substrate 48 and the element separation region 57. Due to the connection portion 51, a predetermined voltage is supplied to the photodiode region PD from the light-blocking wiring 54, and due to this, the potential of the front surface side of the photodiode region PD is controlled. At this time, since the connection portion 51 is connected via the gate insulating film 50 on the substrate 48, the photodiode region PD and the connection portion 51 are not electrically connected.

Then, since both the connection portion 51 and the transfer electrode 56 are both connected to the light-blocking wiring 54, the voltage which is supplied to the photodiode region PD via the connection portion 51 and the voltage which is supplied to the transfer electrode 56 via the contact portion 55 are synchronized.

In FIG. 13, although omitted from the diagram, a color filter layer and an on-chip lens are formed on a back surface side of the substrate 48 in the same manner as a typical back side illumination type of solid-state imaging device. Then, in the solid-state imaging device of the embodiment, there is a configuration where light L is incident from a back surface side of the substrate 48 which is a side opposite to the side where the wiring layer 52 is formed.

Even in the solid-state imaging device 40 of the embodiment, the light L which is incident from a back surface side of the substrate 48 is photoelectrically converted by the photodiode region PD and the signal charge according to the amount of light is generated and accumulated in the charge accumulation region 41. Then, when accumulating charge, a negative voltage is supplied from the light-blocking wiring 54 to the transfer electrode 56 and the photodiode region PD. By doing this, the signal charge which is accumulated in the charge accumulation region 41 is not transferred to the transfer channel portion 59 side. On the other hand, by supplying a negative voltage using the connection portion 51 to the boundary region with the element separation region 57 in the photodiode region PD, there is excitation of the positive holes in the front surface side of the substrate 48. Due to this, a hole pinning effect on the front surface side of the substrate 48 is reinforced and the suppression of dark current is able to be achieved in the photodiode region PD which is connected to the connection portion 51.

After the formation of the transfer electrode 56, the dark current suppressing region 49 is formed using ion implanting via a resist, but ion implanting is difficult at the edge portions of the resist. As a result, the dark current suppressing region 49 is difficult to form in a portion on the edge of the photodiode region PD and the element separating region 57, that is, at the boundary, and there is a tendency for hole pinning to be excluded from this portion. In the embodiment, since the connection portion 51 is provided in the boundary of the photodiode region PD and the element separation region 57 where it is easy for pinning to be excluded and for dark current to be generated, it is possible to suppress dark current from the boundary of the photodiode region PD and the element separation region 57.

In addition, after accumulating charge, a positive voltage is supplied to the transfer electrode 56 and the photodiode region PD from the light-blocking wiring 54. By doing this, the signal charge which is accumulated in the charge accumulation region 41 is read out in the transfer channel portion 59 via the read-out channel portion 60. On the other hand, by supplying a positive voltage using the connection portion 51 to the boundary region with the element separation region 57 in the photodiode region PD, there is excitation of electrons in the front surface side of the substrate 48. Due to this, read-out efficiency is improved and an effect of suppressing residual images is able to be achieved. Otherwise, the same effects as the first embodiment are able to be achieved.

Here, the configurations of the first to the fourth embodiments above may be used in combination and appropriate modifications are possible.

The disclosure is not limited to being applied to a solid-state imaging device where the distribution of an amount of incident visible light is detected and imaged an image, but is also able to be applied to solid-state imaging devices where the distribution of the amount of incidence of infrared rays, X-rays, particles, or the like is imaged as an image. In addition, as a broad meaning, the disclosure is able to be applied to all types of solid-state imaging devices (physical quantities distribution detection devices) such as a fingerprint detection sensor or the like where the distribution of other physical quantities such as pressure or capacitance are detected and imaged as an image.

In addition, the disclosure is not limited to a solid-state imaging device which reads out a image signal from each pixel unit by scanning each pixel unit of a pixel section in order in row units. The disclosure is able to be applied also with regard to an X-Y address type of solid-state imaging device where arbitrary pixels are selected in pixel units and a signal is read out from the selected pixels in pixel units.

Here, the solid-state imaging device may be formed as one chip or may be formed as a module which has an imaging function where a pixel section, a signal processing section and an optical system are collected and packaged.

In addition, the embodiment of the disclosure is not limited to the first to the fourth embodiments, but various modifications are possible. In addition, the examples described above are cases mainly configured using n-channel MOS transistors, but it is possible to configure using p-channel MOS transistors. In a case with p-channel MOS transistors, there is a configuration where the conductive types in each diagram are reversed.

In addition, the disclosure is not limited to being applied to the solid-state imaging device and is able to be applied to an imaging device. Here, the imaging device refers to an electronic apparatus which has a camera system such as a digital still camera, a video camera, or the like, or an imaging function such as a mobile phone device. Here, there is a case where the module format mounted in the electronic apparatus, that is, the camera module is the imaging device.

### 5. Fifth Embodiment: Electronic Apparatus

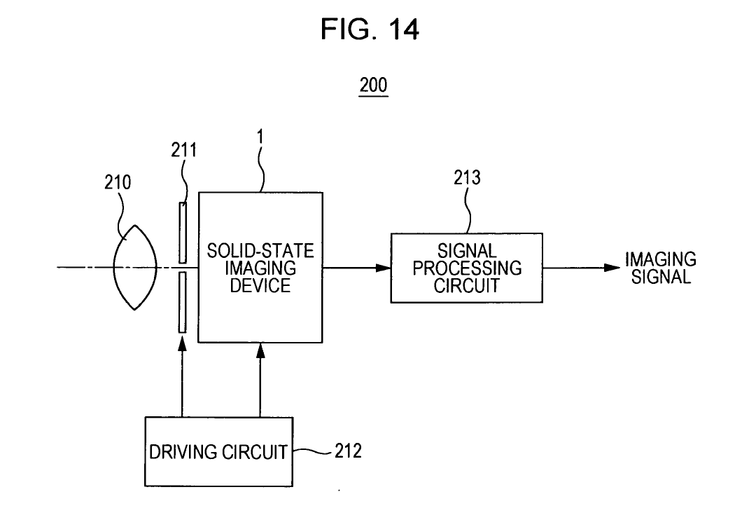

Next, an electronic apparatus according to a fifth embodiment of the disclosure will be described. FIG. 14 is an outline configuration diagram of an electronic apparatus 200 according to a fifth embodiment of the disclosure.

The electronic apparatus 200 of the embodiment shows an embodiment in a case where the solid-state imaging device 1 according to the first embodiment of the disclosure described above is used in an electronic apparatus (a camera).

The electronic apparatus 200 of the embodiment has the solid-state imaging device 1, an optical lens 210, a shutter device 211, a driving circuit 212, and a signal processing circuit 213.

The optical lens 210 images image light (incident light) from a subject on an imaging surface of the solid-state imaging device 1. Due to this, signal charge is accumulated for a constant period of time in the solid-state imaging device 1.

The shutter device 211 controls the period of light irradiation and the period of light blocking in the solid-state imaging device 1.

The driving circuit 212 supplies a driving signal which controls the transfer operation of the solid-state imaging device 1 and the shutter operation of the shutter device 211. The signal transferring in the solid-state imaging device 1 is performed using the control signal (timing signal) supplied from the driving circuit 212. The signal processing circuit 213 performs various types of signal processing. The video signals where signal processing has been performed are stored in a storage medium such as a memory or are output to a monitor.

An improvement in image quality is able to be achieved in the electronic apparatus 200 of the embodiment since suppression of dark current is able to be achieved and color mixing is reduced in the solid-state imaging device 1.

The electronic apparatus 200 which is able to use the solid-state imaging device 1 is not limited to a camera and it is possible to use a digital still camera or an imaging device such as camera module for mobile devices such as mobile phone devices.

The embodiment is a configuration where the solid-state imaging device 1 is used in an electronic apparatus, but it is possible to use the solid-state imaging device which is manufactured using the second to the fourth embodiments described above.

The present disclosure contains subject matter related to that disclosed in Japanese Priority Patent Application JP 2010-241490 filed in the Japan Patent Office on Oct. 27, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging device comprising:
a substrate;
a photodiode region which is formed in the substrate and generates a signal charge using photoelectric conversion of light which is incident from a back surface side of the substrate;
a wiring layer which is formed on a front surface side of the substrate which is a side opposite to a light incidence surface;
a light-blocking wiring which is formed in the wiring layer and is formed in a region which covers at least a portion of the photodiode region; and
a connection portion which supplies a predetermined voltage from the light-blocking wiring to the photodiode region.

2. The solid-state imaging device according to claim 1,
wherein the connection portion is connected to the light-blocking wiring and the substrate via an insulating film formed on a front surface of the substrate.

3. The solid-state imaging device according to claim 1,
wherein the connection portion is formed in at least a portion on the photodiode region side in a boundary region of the photodiode region and an element separation region which is formed in the vicinity of the photodiode region.

4. The solid-state imaging device according to claim 1, further comprising:
a charge read-out region which is formed in a region which is adjacent to the photodiode region on the substrate and reads out the signal charge generated by the photodiode region; and
a charge read-out electrode which is provided on a front surface side of the substrate so as to read out the signal charge generated by the photodiode region to the charge read-out region,
wherein a voltage, which is synchronized with a voltage which is supplied to the photodiode region due to the light-blocking wiring being connected, is supplied in the charge read-out electrode.

5. A manufacturing method of a solid-state imaging device comprising:
forming, on a substrate, a photodiode region, which generates a signal charge using photoelectric conversion of light which is incident from a back surface side of the substrate, and an element separation region, which electrically separates adjacent photodiode regions;
forming an insulting film on a front surface which is a side opposite to a light incidence surface of the substrate;
forming an interlayer insulating film which configures a wiring layer on the insulating film;
forming a connection hole which does not penetrate through the insulating film is formed in the interlayer insulating film on the photodiode region which is formed on the substrate and forming a connection portion by a conductive material being filled into the connection hole; and
forming wiring which configures a wiring layer on the interlayer insulating film and forming light-blocking wiring which is connected to the connection portion and covers at least a portion of the photodiode region.

6. The manufacturing method of a solid-state imaging device according to claim 5,
wherein the connection hole is formed in at least a portion on the photodiode region side in a boundary region of the photodiode region and an element separation region which is formed in the vicinity of the photodiode region.

7. The manufacturing method of a solid-state imaging device according to claim 5, further comprising:
forming a charge read-out region for reading out the signal charge generated by the photodiode region in a region which is adjacent to the photodiode region on the substrate before the forming of the interlayer insulating film;
forming a charge read-out electrode for reading out the signal charge generated by the photodiode region to the charge read-out region on a front surface side of the substrate;
forming a contact hole which exposes the charge read-out electrode in the interlayer insulating film at an upper portion of the charge read-out electrode either before or after the forming of the connection hole; and
forming a contact portion by filling in the contact hole with a conductive material at the same time of filling in the connection hole with the conductive material;
wherein the light-blocking wiring is formed so as to be connected with the connection portion and be connected with the contact portion.

8. An electronic apparatus comprising:
an optical lens;
a solid-state imaging device which is provided with a substrate, a photodiode region which is formed in the substrate and generates a signal charge using photoelectric conversion of light which is incident from a back surface side of the substrate, a wiring layer which is formed on a front surface side of the substrate which is a side opposite to a light incidence surface, a light-blocking wiring which is formed in the wiring layer and is formed in a region which covers at least a portion of the photodiode region, and a connection portion which supplies a predetermined voltage from the light-blocking wiring to the photodiode region, and which is irradiated with light focused by the optical lens; and
a signal processing circuit which processes an output signal which is output from the solid-state imaging device.
